(19) United States
(12) Patent Application Publication
(10) Pub. No.: US 2017/0287720 A1
(43) Pub. Date: Oct. 5, 2017

(54) Methods to Prevent Whisker Growth in Metal Coatings

(71) Applicant: Sandia Corporation, Albuquerque, NM (US)

(72) Inventors: Paul T. Vianco, Albuquerque, NM (US); Jerome A. Rejent, Albuquerque, NM (US)

(21) Appl. No.: 15/466,608

(22) Filed: Mar. 22, 2017

Related U.S. Application Data
(60) Provisional application No. 62/315,991, filed on Mar. 31, 2016.

(51) Int. Cl. H01L 21/285; C23C 14/16

(52) U.S. Cl. CPC H01L 21/28568; H01L 21/2855; C23C 14/16

(57) ABSTRACT

Whisker growth can be prevented in tin coatings by altering the tin film composition) or by modifying the tin/substrate interface.

### CROSS-REFERENCE TO RELATED APPLICATION

This application claims the benefit of U.S. Provisional Application No. 62/315,991, filed Mar. 31, 2016, which is incorporated herein by reference.

### STATEMENT OF GOVERNMENT INTEREST

This invention was made with Government support under contract no. DE-AC04-94AL85000 awarded by the U. S. Department of Energy to Sandia Corporation. The Government has certain rights in the invention.

### FIELD OF THE INVENTION

The present invention relates to electronic materials and, in particular, to methods to prevent whisker growth in metal coatings.

### BACKGROUND OF THE INVENTION

Tin (Sn) whiskers have been of interest to the materials engineering community as a result of the increased use of pure Sn surface finishes in the electronics industry. These Sn whiskers can pose a reliability concern by creating short circuits between electrical conductors. Previously, the engineering solution to this phenomenon was to contaminate the Sn coating with >5 wt. % of Pb for high-reliability electronic components. However, Pb-containing finishes have been replaced with pure Sn coatings (defined as less than 3 wt. % Pb) to meet environmental mandates. More recent mitigation strategies have included alternative surface finishes or physical barriers (e.g., conformal coatings) to prevent electrical short circuits. The attention being given specifically to Sn whiskers stems largely from their impact on engineering applications. However, whisker formation is a general phenomenon that is not limited to only Sn. Other metals and alloys form whiskers, including Cd, In, Zn, Au, Pb, In—Sn, and Sn—Pb. Also, whisker development need not necessarily originate only from thin-film coatings. For example, whiskers have also been observed growing from alloy solder joints, indicating that whisker development is a generalized phenomenon of metals and alloys.

### SUMMARY OF THE INVENTION

The present invention is directed to a method to prevent whisker growth in coatings that form whiskers, such as Sn, Cd, In, Zn, Au, Pb, In—Sn, and Sn—Pb, by alloying additions. For example, the method can comprise alloying tin with about 1 wt. % iron addition. Other alloy additions, such as Bi or In, can also be used. Alternatively, the method can comprise depositing an iron layer on a substrate and depositing a tin layer on the iron layer.

### BRIEF DESCRIPTION OF THE DRAWINGS

The detailed description will refer to the following drawings, wherein like elements are referred to by like numbers.

FIGS. 1(a)-(d) are schematic illustrations showing whisker growth by the DRX mechanism. FIG. 1(a) shows dislocation structures build up strain energy. FIG. 1(b) shows DRX initiation at the right-hand grain boundary. FIG. 1(c) shows DRX grain growth. FIG. 1(d) shows under grain boundary pinning and further DRX causing whisker growth out from the surface.

FIGS. 2(a)-(c) are schematic illustrations showing hillock formation by DRX. FIG. 2(a) shows the DRX process initiation at the grain boundary and momentary pinning creating a small whisker. FIG. 2(b) shows pinning ceasing, allowing lateral growth of the DRX grain until the latter is pinned, again. FIG. 2(c) shows the hillock is complete when the “pinned-unpinned” process slows with the loss of strain energy.

FIGS. 3(a)-(c) are SEM photographs showing the surface of the co-electroplated, Fe—Sn films on Cu coupons for 0.0%, 0.1%, and 1.0% Fe by weight, respectively. The films were 1.0 μm thick and were aged at 60° C. for two days. (No mechanical load.)

FIG. 4(a) is a schematic illustration showing the three factors that control DRX and thus, whisker growth, as presented on the laboratory test sample (Si wafer). The placement of the Fe flash layer under the Sn creates the Sn/Fe interface. FIG. 4(b) is a TEM photograph showing this film structure for the 0.5 μm layer having a 10 nm Fe flash layer (25° C.).

FIGS. 5(a)-(b) are SEM photographs showing the surfaces of the laboratory test samples free of long whiskers and hillocks after aging at 100° C. for nine days. The specimens have these layers: FIG. 5(a) has a 0.5 μm Sn layer on 10 nm Fe. FIG. 5(b) has a 2.0 μm Sn layer on 40 nm Fe.

FIG. 6(a) is an SEM photograph showing the FIB cross section made to the laboratory test samples having 2.0 μm Sn and 40 nm Fe. The sample had been aged at 100° C. for nine days. (The Pt layer is part of the FIB process.) FIG. 6(b) is a TEM image showing the Sn/Fe interface at higher magnification. The yellow box identifies the location of the spectral analysis. FIG. 6(c) is a high magnification SEM image showing the spectral analysis site; the elemental map of the latter is shown to the scale of the yellow box.

### DETAILED DESCRIPTION OF THE INVENTION

Dynamic recrystallization (DRX), in conjunction with long-range diffusion, has been proposed as the mechanism for long whisker growth from the surfaces of metals and alloys. See P. T. Vianco and J. A. Rejent, J. Electronic Materials 38(9), 1815 (2009); and P. T. Vianco and J. A. Rejent, J. Electronic Materials 38(9), 1826 (2009); which are incorporated herein by reference. The DRX mechanism controls actual whisker development while long range diffusion provides the mass transport required to support formation of the structures. According to this model, whiskers and hillocks are manifestations of a single mechanism, and the distinguishing factor is the presence or absence, respectively, of grain boundary pinning. The strain energy generated by anelastic deformation, which is a combination of time-independent deformation (plasticity) and time-dependent deformation (creep), provides the driving force for DRX. The DRX mechanism, when applied to whisker and hillock growth, initiates the growth of new grains in the microstructure. Briefly, there are two cases of DRX: continuous DRX and cyclic DRX. Continuous DRX is characterized by a single grain initiation and growth cycle due to a reduced amount of strain energy. When strain energy is high, there can be multiple cycles of new grain formation and growth, which defines cyclic DRX. Long whiskers and hillocks require cyclic DRX and its more extensive grain growth. Although long-range diffusion is required to provide the material needed to grow whiskers and hillocks, it does not appear to be the controlling mechanism in whisker and hillock growth.

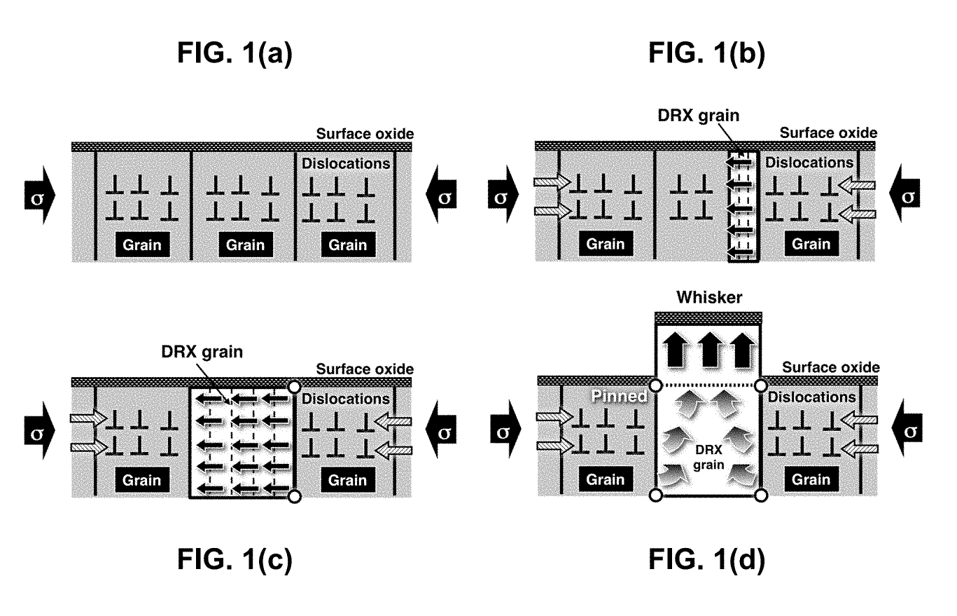

Mechanistically, one sequence of whisker growth by DRX is illustrated in FIGS. 1(a)-(d). As shown in FIG. 1(a), strain energy is built up in the grains by anelastic deformation. As shown in FIG. 1(b), the DRX mechanism initiates at the right-hand grain boundary. The DRX grain boundary grows, as shown in FIG. 1(c). As shown in FIG. 1(d), grain boundary pinning causes further DRX to create a whisker. The whisker grows from the surface as material is brought across the boundaries to reduce the strain energy. In this case, the whisker tip has a similar shape as the pre-existing grain although it is formed by new grain growth underneath it. Grains are three-dimensional structures so that there are other combinations of initiation points, growth direction, and pinning points that can lead to different variants of whisker appearance.

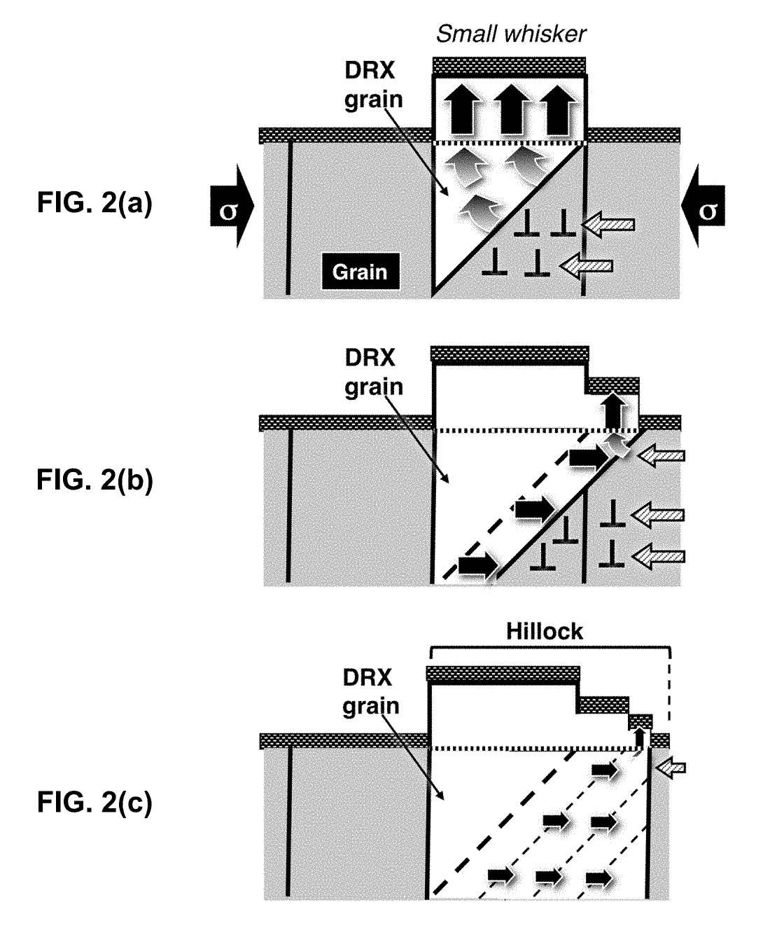

Hillock formation is described schematically in FIGS. 2(a)-(c). Anelastic deformation provides the strain energy for DRX. Growth of a whisker begins in FIG. 2(a) by momentary pinning of the boundary. Pinning is lost, which allows for in-plane growth of the DRX grain as shown in FIG. 2(b). Steps are created by the intermittent pinning of the grain boundary. However, these steps become smaller as strain energy decreases until growth ceases as shown in FIG. 2(c). As was observed with long whiskers, different levels of strain energy, coupled with variations in grain boundary pinning activity, lead to different hillock morphologies.

A quantitative description of the DRX model is described in P. T. Vianco et al., J. Electronic Materials 44(10), 4012 (2015), which is incorporated herein by reference. This model suggests several methods toward mitigating the development of exemplary Sn whiskers. Further, the thin film nature of Sn layers has a critical role in whisker growth by DRX and, as such, can be used to develop mitigation tools. For example, the mobility of grain boundaries determines the propensity for long whiskers to form (pinned boundaries) as opposed to hillocks (mobile boundaries). The latter are preferred because they pose a relatively low risk to electronics reliability. Sn whisker formation can also be considered from the point-of-view of overall system free-energy. The “system” free energy for whisker growth includes these three factors: (a) the metal film (100% or an alloy composition); (b) its exposed surface (metal/atmosphere interfacial energy); and (c) its interface with the substrate (metal/substrate interfacial energy). The mitigation of long-whiskers requires minimizing the system free-energy that drives their growth by altering one or more of these three factors.

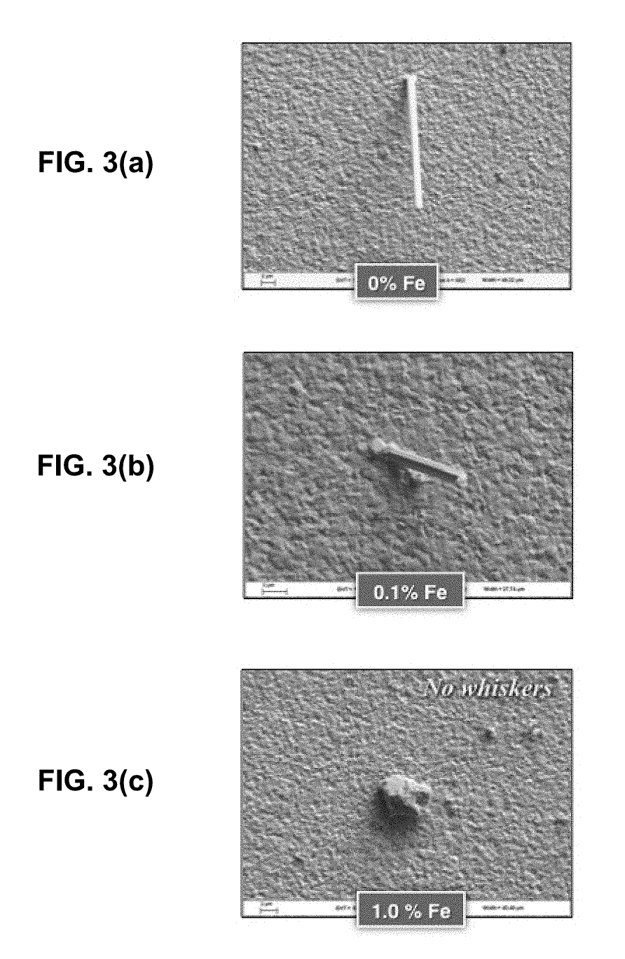

With regards to factor (a), alloying additions can be used to prevent the formation of long-whiskers. For example, as shown in FIG. 3(a)-(c), additions of 1.0% Fe to the Sn layer are effective at eliminating long-whiskers from Sn layers evaporated on Si wafers. Too much larger Fe additions may cause solderability problems due to Fe-oxide formation on the coatings, which may not be removed by electronic fluxes. Of course, if the alloy addition is too low, whiskers will form. Therefore, the alloy addition is preferably between about 0.1 and 2.0 wt. % Fe. Similar whisker elimination can be obtained with Sn—Fe layers evaporated on electroplated Cu, Ni, and Fe—Ni—Co substrates, which are more representative of industrial applications. Alloy additions can be used to mitigate whisker growth in other transition and post-transition metals that are known to form whiskers, such as Cd, In, Zn, Au, Pb, In—Sn, and Sn—Pb. Indium or bismuth can also be used as alloy additions to these metals.

With regards to factor (b), it is difficult to alter the exposed surface of a Sn layer from a practicality standpoint, because of the potential impact on solderability.

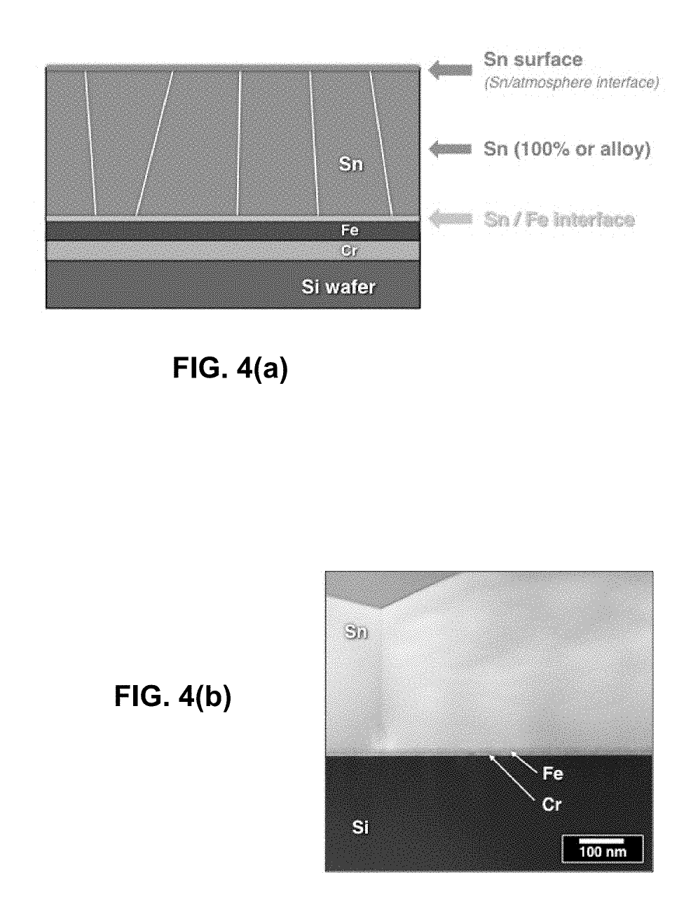

With regards to factor (c), changing the metal/substrate interface can also be used to control whisker growth. For example, an intervening flash layer of preferably 10 to 100 nm thickness can be adequate to minimize metal/substrate interfacial energy and prevent whisker growth. As an example of this method, samples were prepared by evaporating Sn layers on Si wafers. After deposition of a 20 nm Cr adhesion layer, a 10 nm or 40 nm layer of Fe was evaporated on the surface, followed by a 0.5 μm or 2.0 μm layer of Sn, respectively. A schematic diagram of this sample configuration is shown in FIG. 4(a); a transmission electron microscope (TEM) image of the 0.5 μm Sn/10 nm Fe sample is shown in FIG. 4(b). The samples were exposed to the aging temperatures of 25° C., 60° C., or 100° C. for nine days. All layers remained adherent to one-another.

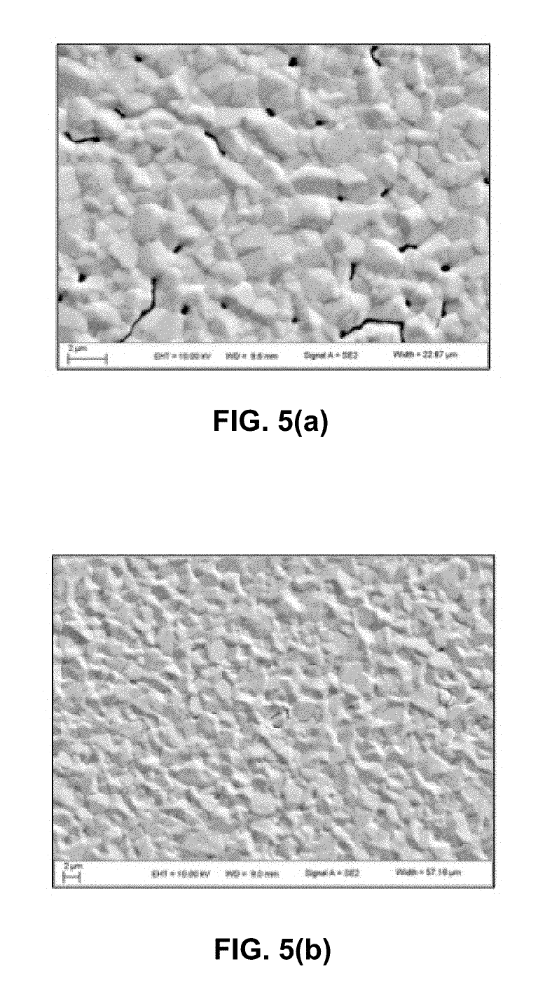

Microanalysis included scanning electron microscopy (SEM) images made of the Sn film surfaces. This result is exemplified by the two SEM images FIGS. 5(a) and 5(b), which show the surfaces of the 0.5 μm Sn/10 nm Fe and 2.0 μm/40 nm Fe samples, respectively. Long whiskers, as well as hillocks, were absent from all of the test samples.

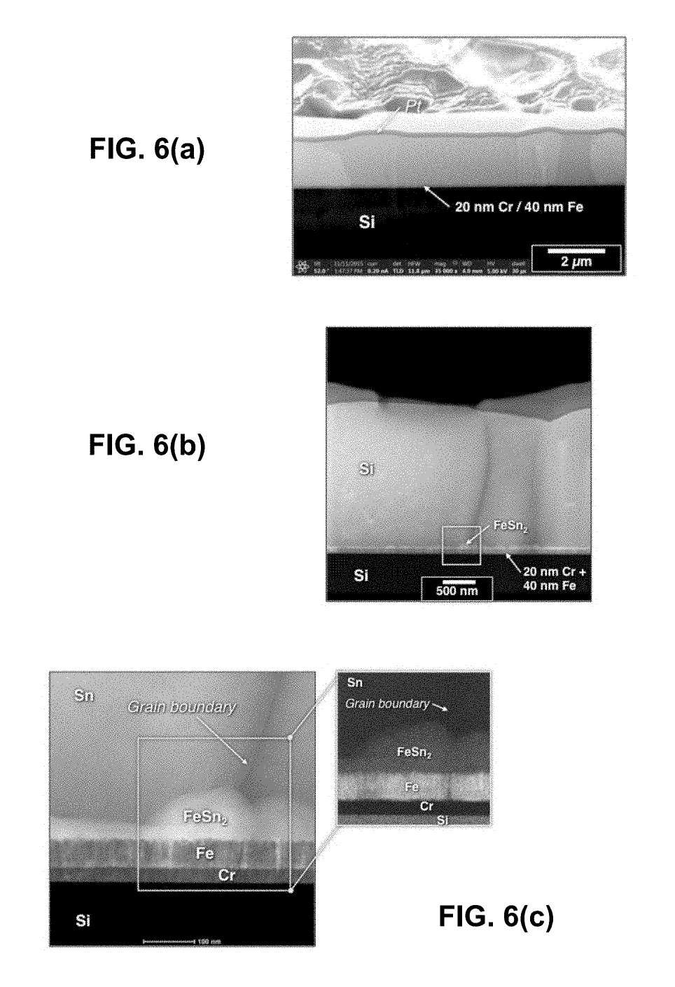

Additional microanalysis was performed to document the interactions between Fe and Sn in order to identify, more specifically, the mechanism(s) responsible for mitigating whiskers. The focused ion-beam (FIB) cross section is shown by the SEM image in FIG. 6(a), which was taken of the 2.0 μm Sn/40 nm Fe sample aged for nine days at 100° C. At this magnification, there were no indications of extensive interdiffusion and/or reaction between the Sn and Fe layers. A further assessment was made of the Sn/Fe interface using the greater magnification capabilities of the TEM in conjunction with elemental mapping provided by spectral analysis. The TEM image in FIG. 6(b) shows FeSn₂ intermetallic compound formation along the Sn/Fe interface. However, the reaction layer was very thin, being limited to less than 0.25 μm.

A spectral analysis was performed on the two variants of Sn/Fe structures exposed to 25° C. and 100° C. for nine days. Those results are shown in FIG. 6(c) for the same 2.0 μm Sn/40 nm Fe specimen shown in FIG. 6(a). This analysis confirmed that there was negligible Fe bulk diffusion into the Sn layers. Grain boundary diffusion occurred at only a few triple point locations where the Sn boundary intercepted the Fe layer and only in the samples aged at 25° C. Aging at higher temperatures only led to the formation of FeSn₂ at the exclusion of Fe Vianco et al.

grain boundary diffusion. When grain boundary diffusion occurred, it was limited to distances of less than 0.25 μm.

Therefore, the mitigation of long-whiskers and hillocks resulted from a reduction of the driving force for DRX by altering the Sn/substrate interfacial energy—in this case, the addition of Fe to create the Sn/Fe interface. The Fe flash layer can be used with industrial samples based upon Cu substrates and electroplated Fe and Sn finishes. An added advantage of the Fe flash layer as opposed to alloying the Sn layer, from the applications standpoint, is that it is easier to implement an electroplating process based upon layer depositions than it is to optimize the performance alloy plating baths.

The present invention has been described as methods to prevent whisker growth in tin coatings. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A method to prevent whisker growth in a metal layer, comprising:
depositing a metal layer on a substrate, wherein the metal comprises an alloy addition sufficient to prevent whisker growth in the metal layer.

2. The method of claim 1, wherein the metal comprises Sn.

3. The method of claim 1, wherein the metal comprises Cd, In, Zn, Au, Pb, In—Sn, or Sn—Pb.

4. The method of claim 1, wherein the alloy addition comprises Fe.

5. The method of claim 1, wherein the alloy addition comprises Bi or In.

6. The method of claim 1, wherein the alloy addition is between 0.1 and 2.0 wt. %.

7. The method of claim 1, wherein the substrate comprises silicon, copper, nickel, or Fe—Ni—Co.

8. The method of claim 1, wherein the thickness of the metal layer is less than 2 μm.

9. A method to prevent whisker growth in a tin layer, comprising:
depositing an iron layer on a substrate, and depositing a tin layer on the iron layer.

10. The method of claim 9, wherein the substrate comprises silicon, copper, nickel, or Fe—Ni—Co.

11. The method of claim 9, wherein the thickness of the iron layer is less than 2 μm.
